(19) United States
(12) Patent Application Publication
(10) Pub. No.: US 2006/0022746 A1
(43) Pub. Date: Feb. 2, 2006

(54) Output driver for passive matrix organic light emitting diode

(76) Inventor: Jeong-Min Kim, Chungcheongbuk-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/193,649

(22) Filed: Jul. 28, 2005

(30) Foreign Application Priority Data
Jul. 29, 2004 (KR) 2004-0059528

(51) Int. Cl. G05F 1/10

(52) U.S. Cl. 327/543

(57) ABSTRACT

An output driver capable of reducing a leakage current is provided. In the output driver, a low voltage analog part is connected to a low voltage terminal and generates a mirror current proportional to an inputted current. A high voltage output driver is connected to a high voltage terminal and a current flows through the high voltage output driver when the mirror current flows. A switch selectively connects the low voltage analog part and the high voltage output driver. At least one compensation diode is disposed between the high voltage output driver and the switch.

### FIELD OF THE INVENTION

The present invention relates to a passive matrix organic light emitting diode (PMOLED); and, more particularly, to an output driver, which is capable of preventing a leakage current, for used in the PMOLED.

### DESCRIPTION OF RELATED ART

FIG. 1 is a circuit diagram showing a conventional output driver in a PMOLED.

As shown, a PWM switch 120 is connected between a low voltage analog part 110 and a high voltage output driver 130. If a current I flows through a first NMOS transistor 112 of the low voltage analog part 110, the same current I flows through a third NMOS transistor 116 thereof due to a current mirror effect. Accordingly, a current is generated in a high voltage PMOS transistor of the high voltage output driver 130. At this time, a voltage V2 applied to a drain of the PWM switch 120 is determined by the current I flowing through the first NMOS transistor 112 of the low voltage analog part 110. That is, if a small current I flows and a gate-source voltage (V_{gs}) of the PWM switch 120 rises above a threshold voltage, the PWM switch 120 is turned on. In this case, about 18 V is supplied to a high voltage terminal Vout of the high voltage output driver 130, about 14 to 15 V is derived to the drain of the PWM switch 120. Consequently, a drain-source voltage (V_{ds}) of the PWM switch 120 is relatively much higher than the gate-source voltage (V_{gs}) and thus a substrate current I_{sub} flows from the drain to a substrate in the PWM switch 120.

FIG. 2 is a waveform of a leakage current measured in a conventional PMOLED.

Referring to 2, a leakage substrate current I_{sub} is given by following equations.

$${I}_{sub} = ( {α}_{1} + \frac{{α}_{0}}{{L}_{eff}} ) ( {V}_{ds} - {V}_{dseff} ) exp ( - \frac{{β}_{0}}{{V}_{ds} - {V}_{dseff}} ) {I}_{dsa}$$

$${I}_{dsa} = \frac{{I}_{dsa}}{1 + \frac{{R}_{ds} {I}_{dso}}{{V}_{dseff}}} ↔ ( 1 + \frac{{V}_{ds} - {V}_{dseff}}{{V}_{A}} )$$

where α₀ is a first parameter of an impact ionization current,
α₁ is an impact ionization constant,
β₀ is a second parameter of the impact ionization current,
L_{eff} is an effective length of the PWM switch,
V_{dseff} is an effective drain voltage,
I_{dsa} is a drain saturation current, and
Vₐ is an early voltage.

It can be seen from the above equation that the substrate current I_{sub} increases when the drain voltage V_{d} increases. A condition A is that V_{g}=3V and Vₛ=1.2V are supplied to the MOS transistor of the high voltage output driver 130, and a condition B is that V_{g}=2.6V and Vₛ=0.8V are supplied to the MOS transistor of the high voltage output driver 130. In both of the conditions A and B, as the drain voltage of the PWM switch increases, the leakage substrate current also increases.

Consequently, at a low current, the drain voltage of the PWM switch 120 increases much and thus the leakage current flowing from the drain to the substrate increases. Although this leakage current is different based on the applied voltage, unnecessary power consumption increases as the channels increases.

### SUMMARY OF THE INVENTION

It is, therefore, an object of the present invention to provide a leakage preventing circuit for use in an output driver, which is capable of reducing a leakage current.

In accordance with aspect of the present invention, there is provided an output driver for a PMOLED, including: a low voltage analog part, connected to a low voltage terminal, for generating a mirror current proportional to an inputted current; a high voltage output driver connected to a high voltage terminal, wherein a current flows through the high voltage output driver when the mirror current flows; a switch for selectively connecting the low voltage analog part to the high voltage output driver; and at least one compensation diode disposed between the high voltage output driver and the switch.

Preferably, the compensation diode may be configured with a MOS transistor.

Preferably, the low voltage analog part may be a current mirror having one terminal connected to the low voltage terminal and generating the mirror current proportional to the inputted current.

In accordance with another aspect of the present invention, there is provided an output driver for a PMOLED, including: a first high voltage driver connected to a high voltage terminal, the first high voltage driver being controlled by an inputted current; a second high voltage driver, connected to a low voltage terminal, for mirroring a current transferred from the first high voltage driver and generating a mirror current; and at least one compensation diode disposed between the first high voltage driver and the second high voltage driver.

Preferably, the compensation diode may be configured with a MOS transistor.

Preferably, the second high voltage driver may be a current mirror having one terminal connected to the low voltage terminal and generating the mirror current.

### BRIEF DESCRIPTION OF THE DRAWINGS

The above and other objects and features of the instant invention will become apparent from the following description of preferred embodiments taken in conjunction with the accompanying drawings, in which:

FIG. 1 is a circuit diagram showing a conventional output driver;

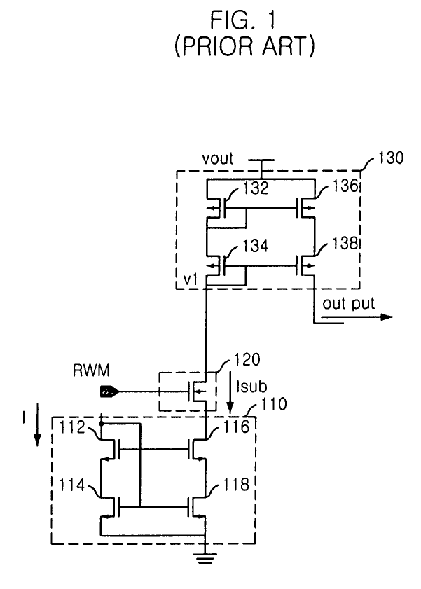

FIG. 2 is a waveform describing a leakage current in FIG. 1;

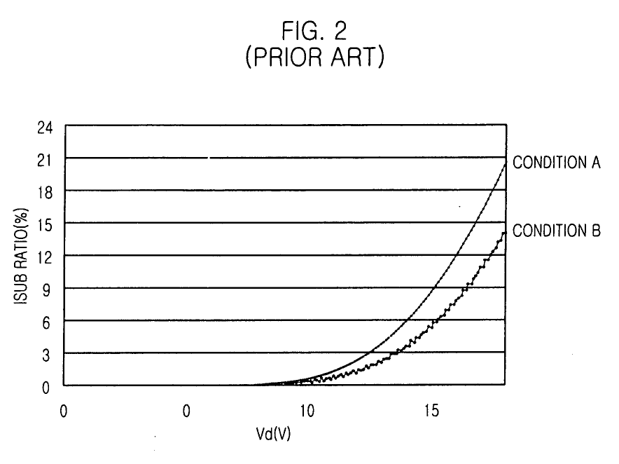

FIG. 3 is a circuit diagram depicting an output driver in accordance with an embodiment of the present invention; and

FIG. 4 is a circuit diagram depicting an output driver in accordance with another embodiment of the present invention.

### DETAILED DESCRIPTION OF THE INVENTION

Other objects and aspects of the invention will become apparent from the following description of the embodiments with reference to the accompanying drawings, which is set forth hereinafter.

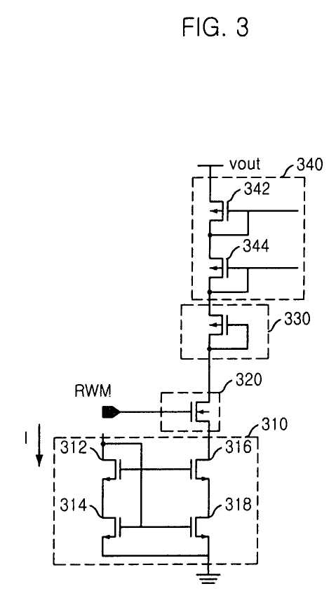

FIG. 3 is a circuit diagram of an output driver for a PMOLED in accordance with an embodiment of the present invention.

As shown, the output driver for the PMOLED includes a low voltage analog part 310, a high voltage output driver 340, a PWM switch 320, and at least MOS-type compensation diode 330. For simplicity, only one MOS-type compensation diode is shown in FIG. 3. The PWM switch 320 selectively connects the low voltage analog part 310 and the high voltage output driver 340. The MOS-type compensation diode 330 is disposed between the PWM switch 320 and the high voltage output driver 340 so as to reduce a drain voltage of the PWM switch 320. Accordingly, a voltage (V_{d}) applied to a drain of the PWM switch 320 is reduced as much as a forward voltage drop of the serially-connected compensation diode 330. Meanwhile, the high voltage output driver 340 includes first and second PMOS transistors 342 and 344 and third and fourth PMOS transistors (not shown) with the same size. Therefore, the high voltage output driver 340 provides the same characteristic as the low voltage analog part 310.

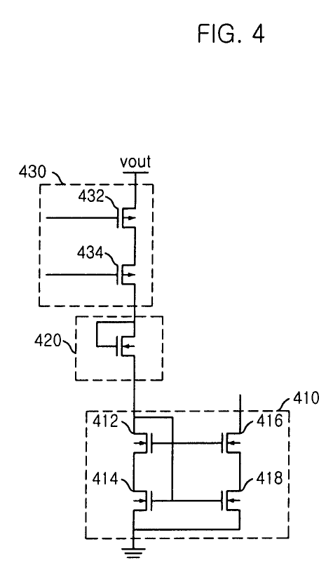

FIG. 4 is a circuit diagram of an output driver in accordance with another embodiment of the present invention.

Referring to FIG. 4, the output driver includes a first high voltage driver 430, a second high voltage driver 410, and at least one MOS-type compensation diode 420. For simplicity, only one MOS-type compensation diode is shown in FIG. 4. The MOS-type compensation diode 420 is disposed between the first high voltage driver 430 and the second high voltage driver 410. It is apparent that a plurality of MOS-type diodes can be connected in series. A voltage applied to a drain of an NMOS transistor 412 in the second high voltage driver 410 is reduced as much as a forward voltage drop of the serially-connected compensation diode. Meanwhile, the first high voltage driver 430 includes first and second PMOS transistors 432 and 434 and third and fourth PMOS transistors (not shown) with the same size. Therefore, the first high voltage driver 430 provides the same characteristic as the second high voltage driver 410.

In accordance with the present invention, the leakage current in the output driver of the PMOLED can be reduced.

The present application contains subject matter related to Korean patent application No. 2004-59528, filed in the Korean Patent Office on Jul. 29, 2004, the entire contents of which is incorporated herein by reference.

While the present invention has been described with respect to certain preferred embodiments, it will be apparent to those skilled in the art that various changes and modifications may be made without departing from the scope of the invention as defined in the following claims.

What is claimed is:

1. An output driver for a passive matrix organic light emitting diode (PMOLED), comprising:
a low voltage analog part, connected to a low voltage terminal, for generating a mirror current proportional to an inputted current;
a high voltage output driver connected to a high voltage terminal, wherein a current flows through the high voltage output driver when the mirror current flows;
a switch for selectively connecting the low voltage analog part to the high voltage output driver; and
at least one compensation diode disposed between the high voltage output driver and the switch.

2. The output driver as recited in claim 1, wherein the compensation diode is configured with a MOS transistor.

3. The output driver as recited in claim 2, wherein the low voltage analog part is a current mirror having one terminal connected to the low voltage terminal and generating the mirror current proportional to the inputted current.

4. An output driver for a passive matrix organic light emitting diode (PMOLED), comprising:
a first high voltage driver connected to a high voltage terminal, the first high voltage driver being controlled by an inputted current;
a second high voltage driver, connected to a low voltage terminal, for mirroring a current transferred from the first high voltage driver and generating a mirror current; and
at least one compensation diode disposed between the first high voltage driver and the second high voltage driver.

5. The output driver as recited in claim 4, wherein the compensation diode is configured with a MOS transistor.

6. The output driver as recited in claim 5, wherein the second high voltage driver is a current mirror having one terminal connected to the low voltage terminal and generating the mirror current.
